(19) United States
(12) Patent Application Publication
(10) Pub. No.: US 2026/0018552 A1
(43) Pub. Date: Jan. 15, 2026

(54) Systems and Methods for Forming Thermal Interface Material on Substrates

(71) Applicant: Applied Materials, Inc., Santa Clara, CA (US)

(72) Inventors: Keith-Kwong-Hon WONG, Wappingers Falls, NY (US); Kun LI, Delmar, NY (US); Jason APPELL, Malta, NY (US); Seth KNUPP, Schenectady, NY (US); Joseph SHEPARD, Saratoga Springs, NY (US); Daniel Konrad Paul TIRE, Schenectady, NY (US)

(21) Appl. No.: 18/767,388

(22) Filed: Jul. 9, 2024

(51) Int. Cl. H01L 23/00; C23C 14/06; C23C 14/58; H01J 37/34

(52) U.S. Cl. CPC H01L 24/27; H01J 37/3426; H01J 37/3464; H01L 24/29; H01L 24/83; C23C 14/0641; C23C 14/588; H01J 2237/332; H01L 2224/2745; H01L 2224/29186; H01L 2224/83895

(57) ABSTRACT

Methods and apparatus for processing a substrate include sputtering a first seed layer having a first thickness on the substrate, the first seed layer comprising a thermal interface material having a tilted crystallographic orientation with respect to the substrate; sputtering a second layer having a second thickness on the first seed layer, the second layer comprising the thermal interface material; and polishing the second layer until a surface roughness of the second layer is suitable for at least one of fusion bonding, thermal compression bonding, or hybrid bonding.

### FIELD

Embodiments of the present disclosure generally relate to substrate processing and more particularly to systems and methods for forming thermal interface materials on substrates.

### BACKGROUND

Hybrid bonding refers to processes for bonding substrates (e.g., die-to-wafer (D2W) or wafer-to-wafer (W2W)) together. Often a thermal interface material, such as aluminum nitride (AlN), forms a bonding surface of at least one of the substrates to be bonded.

Some methods of depositing AlN on substrates include metal-organic chemical vapor deposition (MOCVD) on sapphire substrates, molecular beam epitaxy, pulse laser deposition, and physical vapor deposition (PVD). MOCVD on sapphire substrates, molecular beam epitaxy, and pulse laser deposition for AlN deposition are uneconomical and have low throughput for use in deposition on substrates for hybrid bonding.

PVD, however, can provide a lower cost and higher throughput process in comparison to metal-organic chemical vapor deposition (MOCVD) on sapphire substrates, molecular beam epitaxy, pulse laser deposition. Also, PVD equipment is widely available and process-compatible with silicon substrates having common sizes and formats used in semiconductor manufacturing.

Embodiments described herein include apparatus and methods that can deposit a thermal interface material using PVD, which can thereby reduce costs and increase throughput.

### SUMMARY

Methods and apparatus for substrate processing are provided herein. In some embodiments, a method for processing a substrate includes sputtering a first seed layer having a first thickness on the substrate, the first seed layer comprising a thermal interface material having a tilted crystallographic orientation with respect to the substrate; sputtering a second layer having a second thickness on the first seed layer, the second layer comprising the thermal interface material; and polishing the second layer until a surface roughness of the second layer is suitable for at least one of fusion bonding, thermal compression bonding, or hybrid bonding.

According to some embodiments, a method of processing a substrate includes: sputtering a layer of a thermal interface material on a <111> crystallographic substrate; and polishing the layer until a surface roughness of the layer is suitable for at least one of fusion bonding, thermal compression bonding, or hybrid bonding.

According to some embodiments, a system for processing a substrate includes: at least one PVD chamber; a polishing chamber, and a controller configured to control the at least one PVD chamber and the polishing chamber to: sputter a layer of aluminum nitride on the substrate; and polish the layer until a surface roughness Ra of the layer is 0.2 to 2 nm.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 depicts a schematic, cross-sectional view of a system for substrate processing in accordance with some embodiments of the present disclosure.

FIG. 2A is a side cross-sectional view of a PVD chamber that may be used in the substrate processing system of FIG. 1, according to some embodiments of the present disclosure.

FIG. 2B is an enlarged cross-sectional view of a portion of the PVD chamber of FIG. 2A, according to some embodiments of the present disclosure.

FIG. 3 is a side cross-sectional view of a PVD chamber that may be used in the substrate processing system of FIG. 1, according to some embodiments of the present disclosure.

FIG. 4 depicts a method for substrate processing in accordance with some embodiments of the present disclosure.

FIG. 5 depicts a method for substrate processing in accordance with some embodiments of the present disclosure.

FIGS. 6A-6C schematically depict hybrid bonding of substrates in accordance with some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of apparatus and methods of substrate processing are provided herein. Systems and methods are provided for depositing and polishing thermal interface material on substrates that are suitable for at least one of fusion bonding, thermal compression bonding, or hybrid bonding. In comparison to other methods of deposition discussed above, the systems and methods described herein utilize PVD deposition, which can provide cost and throughput advantages.

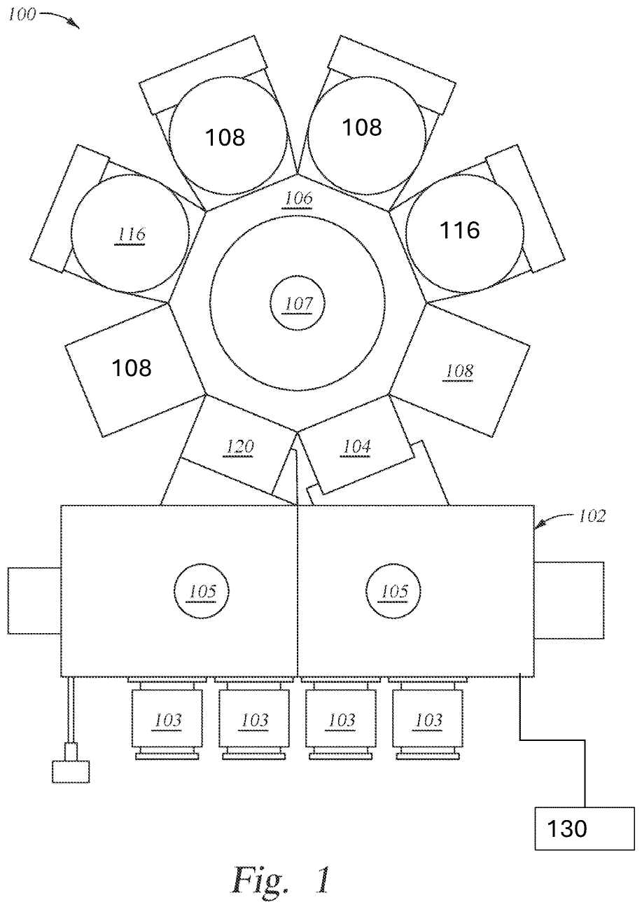

FIG. 1 depicts a system 100 for substrate processing in accordance with some embodiments of the present disclosure. In some embodiments, and as shown in FIG. 1, the system 100 may be configured as one or more cluster tools (e.g., Opta™ CMP, Endura® Impulse™ PVD, and Endura® Clover® PVD, commercially available from Applied Materials Inc., Santa Clara, California) comprised of a plurality of chambers configured for substrate processing.

The system 100 may include an equipment front-end module (EFEM) 102 for loading substrates into the system 100, a first load lock chamber 104 coupled to the EFEM 102, a transfer chamber 106 coupled to the first load lock chamber 104, and a plurality of other chambers coupled to the transfer chamber 106 as described in detail below. The front-end module (EFEM) 102 generally includes one or more robots 105 that are configured to transfer substrates from the FOUPs 103 to at least one of the first load lock chamber 104 or the second load lock chamber 120. The system 100 may include one or more polishing chambers 108, one or more deposition chambers 116, and a second load lock chamber 120. The system 100 may include one or more hybrid bonding chambers. In some embodiments, multiple systems 100 may be used and configured for specific processes, such as polishing and deposition. For example, in some embodiments, one system 100 may be configured for polishing and may include one or more polishing chambers 108, and another system 100 may be configured for deposition and may include one or more deposition chambers 116. Alternatively, at least one of the deposition chamber, or the polishing chamber, or the hybrid bonding chamber can be a standalone chamber and the substrate can be appropriately transferred therebetween for processing in accordance with the teachings provided herein.

In some embodiments, the deposition chamber 116 may be a PVD chamber configured to deposit thermal interface material (e.g., aluminum nitride, boron nitride, diamond) onto a substrate. In some embodiments, the thermal interface material is a dielectric. As used herein, a thermal interface material refers to a material of a certain thickness having a thermal conductivity of 25 to 140 W/mK. An example of a thermal interface material is aluminum nitride (AlN).

The polishing chamber 108 may be configured to perform chemical mechanical polishing (CMP). The polishing chamber 108 may be a CMP chamber of an Opta™ CMP system, commercially available from Applied Materials Inc., Santa Clara, California. The polishing chamber 108 is configured to perform polishing operations to achieve a surface roughness of a layer of thermal interface material that is suitable for at least one of fusion bonding, thermal compression bonding, or hybrid bonding.

In some embodiments, the transfer chamber 106 and each chamber coupled to the transfer chamber 106 are maintained at a vacuum state. As used herein, the term “vacuum” may refer to pressures less than 760 Torr, and will typically be maintained at pressures near 10⁻⁵ Torr (i.e., ^{˜}10⁻³ Pa). However, some high-vacuum systems may operate below near 10⁻⁷ Torr (i.e., ^{˜}10⁻⁵ Pa). In some embodiments, the vacuum is created using a pump coupled to the transfer chamber 106 and to each of the one or more process chambers (e.g., polishing chamber 108, deposition chamber 116).

In some embodiments, substrates are loaded into the system 100 through a door (also referred to as an “access port”), in the first load lock chamber 104 and unloaded from the processing system 100 through a door in the second load lock chamber 120. In some embodiments, a stack of substrates is supported in a cassette disposed in the FOUP, and are transferred therefrom by a robot 105 to the first load lock chamber 104. Once vacuum is pulled in the first load lock chamber 104, one substrate at a time is retrieved from the first load lock chamber 104 using a robot 107 located in the transfer chamber 106. In some embodiments, a cassette is disposed within the first load lock chamber 104 and/or the second load lock chamber 120 to allow multiple substrates to be stacked and retained therein before being received by the robot 107 in the transfer chamber 106 or robot 105 in the EFEM 102. However, other loading and unloading configurations are also contemplated.

In some embodiments, only one substrate is processed within each polishing chamber 108 and deposition chamber 116 at a time. Alternatively, multiple substrates may be processed at one time. In such embodiments, the substrates may be disposed on a rotatable pallet within the respective chambers.

The system 100 may also include a controller 130 configured to control one or more operations of the system 100, such as controlling the operations of the deposition chamber 116 and the polishing chamber 108. In some embodiments, the controller 130 is configured to control the deposition chamber 116 (and/or other deposition chambers, to sputter a layer of thermal interface material, such as AlN, on the substrate, and control the polishing chamber to polish the layer until a surface roughness of the layer is suitable for at least one of fusion bonding, thermal compression bonding, or hybrid bonding (e.g., until a surface roughness Ra of the layer is 0.2 nm to 2 nm).

In some embodiments, the controller 130 may be configured to control the deposition chamber 116 to sputter a bulk layer of thermal interface material (e.g., AlN) directly onto a substrate. In some embodiments, where the substrate is <111> crystallographic silicon, thermal interface material may be sputtered directly onto the substrate. In some embodiments, where the substrate is <100> crystallographic, the thermal interface material may be sputtered onto a seed layer of thermal interface material that has been previously sputtered onto the substrate, as discussed more fully below.

In some embodiments, the controller 130 may be further configured to control at least one deposition chamber 116 to sputter a seed layer of thermal interface material (e.g., aluminum nitride) onto the substrate before sputtering the bulk layer. The seed layer has a thickness that is less than a thickness of the bulk layer. The controller 130 may be configured to control the deposition chamber 116 to sputter the seed layer at a first power density and sputter the bulk layer at a second power density that is higher than the first power density.

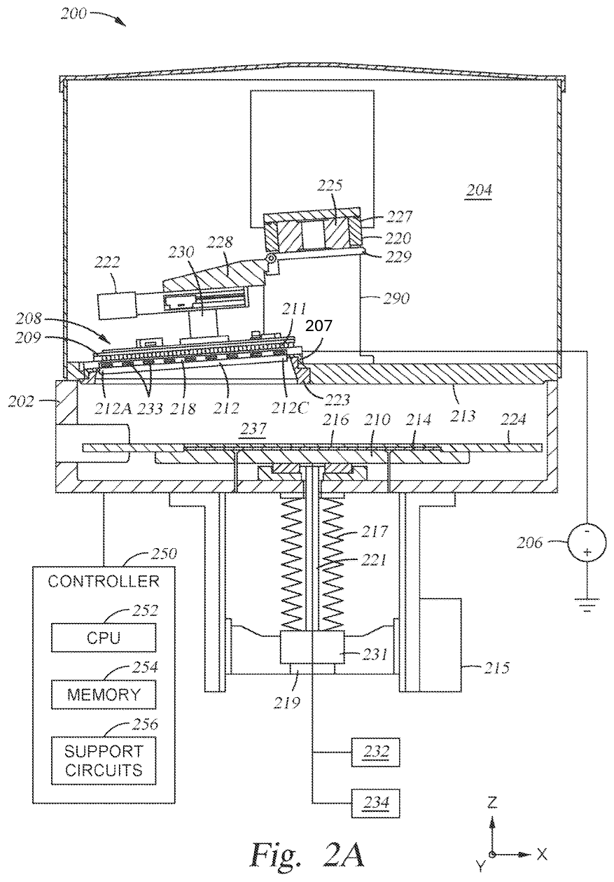

FIG. 2A is a side cross-sectional view of a PVD chamber 200 that may be used in the system 100 of FIG. 1, according to some embodiments. For example, the PVD chamber 200 may represent at least one deposition chamber 116 shown in FIG. 1. FIG. 2B is an enlarged cross-sectional view of a portion of the PVD chamber 200 of FIG. 2A, according to some embodiments. FIGS. 2A-2B are, therefore, described together herein for clarity. In some embodiments, the PVD chamber 200 may be used for depositing a seed layer of thermal interface material on a substrate. As discussed more fully below, the PVD chamber 200 is configured to orient a sputter target and a substrate with a range of non-parallel angles to one another which may result in the deposition of an angled nucleation layer (also referred to as a seed layer) that advantageously allows a further layer of thermal interface material to be deposited and polished uniformly for hybrid bonding applications.

The PVD chamber 200 generally includes a chamber body 202, a lid assembly 204 coupled to the chamber body 202, a magnetron 208 coupled to the lid assembly 204, a pedestal 210 disposed within the chamber body 202, and a target 212 disposed between the magnetron 208 and the pedestal 210. During processing, the interior of the PVD chamber 200, or processing region 237, is maintained at a vacuum pressure. In some embodiments, the vacuum pressure may be 0.5-2 mTorr. The processing region 237 is generally defined by the chamber body 202 and the lid assembly 204, such that the processing region 237 is primarily disposed between the target 212 and the substrate supporting surface of the pedestal 210.

A power source 206 is electrically connected to the target 212 to apply a negatively biased voltage to the target 212. In some embodiments, the power source 206 is a pulsed DC mode source. However, other types of power sources are also contemplated, such as radio frequency (RF) sources. In some embodiments, the power density applied to the target may be 1-3 W/cm².

The target 212 includes a target material 212M and a backing plate 218, and is part of the lid assembly 204. A front surface of the target material 212M of the target 212 defines a portion of the processing region 237. The backing plate 218 is disposed between the magnetron 208 and target material 212M (FIG. 2B) of the target 212, wherein, in some embodiments, the target material 212M is bonded to the backing plate 218. Typically, the backing plate 218 is an integral part of the target 212 and thus for simplicity of discussion the pair may be referred to collectively as the “target.” The backing plate 218 is electrically insulated from the support plate 213 of the lid assembly 204 by use of an electrical insulator 207 to prevent an electrical short being created between the backing plate 218 and the support plate 213 of the grounded lid assembly 204. As shown in FIG. 2A, the backing plate 218 has a plurality of cooling channels 233 configured to receive a coolant (e.g., deionized water) therethrough to cool or control the temperature of the target 212. In some embodiments, the backing plate 218 may have one or more cooling channels. In some examples, the plurality of cooling channels 233 may be interconnected and/or form a serpentine path through the body of the backing plate 218. A shield 223 is coupled to the support plate 213. The shield 223 prevents material sputtered from the target 212 from depositing a film on the support plate 213.

As shown in FIG. 2A, the magnetron 208 is disposed over a portion of the target 212, and in a region of the lid assembly 204 that is maintained at atmospheric pressure. The magnetron 208 includes a magnet plate 209 (or yoke) and a plurality of permanent magnets 211 attached to the shunt plate. The magnets 211 are arranged in one or more closed loops. Each of the one or more closed loops will include magnets that are positioned and oriented relative to their pole (i.e., north (N) and south(S) poles) so that a magnetic field spans from one loop to the next or between different portions of a loop. The sizes, shapes, magnetic field strength and distribution of the individual magnets 211 are generally selected to create a desirable erosion pattern across the surface of the target 212 when used in combination with oscillation of the magnetron 208 as described below. In some embodiments, the magnetron 208 may include a plurality of electromagnets in place of the permanent magnets 211.

The pedestal 210 has an upper surface 214 supporting a substrate 216. A clamp 224 is used to hold the substrate 216 on the upper surface 214. In some embodiments, the clamp 224 operates mechanically. For example, the weight of the clamp 224 may hold the substrate 216 in place. In some embodiments, the clamp 224 is lifted by pins that are movable relative to the pedestal 210 to contact an underside of the clamp 224.

In some embodiments, and as shown in FIG. 2A, the backside of the substrate 216 is in contact with the upper surface 214 of the pedestal 210. In some examples, the entire backside of the substrate 216 may be in electrical and thermal contact with the upper surface 214 of the pedestal 210. The temperature of the substrate 216 may be controlled using a temperature control system 232.

In some embodiments, the temperature control system 232 is configured to maintain the temperature of the substrate 216 to be 20-50° C. In some embodiments, the temperature control system 232 may have an external cooling source that supplies coolant to the pedestal 210. In some embodiments, the external cooling source may be configured to deliver a cryogenically cooled fluid (e.g., Galden®) to heat exchanging elements (e.g., coolant flow paths) within a substrate supporting portion of the pedestal 210 that is adjacent to the upper surface 214, in order to control the temperature of the substrate to a temperature that is less than 20° C., such as less than 0° C., such as about −20° C. or less. In some embodiments, the temperature control system 232 includes a heat exchanger and/or backside gas flow within the pedestal 210. In some examples, the cooling source may be replaced or augmented with a heating source to increase the workpiece temperature independent of the heat generated during the sputtering process. Controlling the temperature of the substrate 216 facilitates the sputtering process to obtain a predictable and reliable thin film.

In some embodiments, a RF bias source 234 is electrically coupled to the pedestal 210 to bias the substrate 216 during the sputtering process. Alternatively, the pedestal 210 may be grounded, floated, or biased with only a DC voltage source. Biasing the substrate 216 can improve film density, adhesion, and material reactivity on the substrate surface.

A pedestal shaft 221 is coupled to an underside of the pedestal 210. A rotary union 219 is coupled to a lower end of the pedestal shaft 221 to provide rotary fluid coupling with the temperature control system 232 and rotary electrical coupling with the RF bias source 234. In some embodiments, a copper tube is disposed through the pedestal shaft 221 to couple both fluids and electricity to the pedestal 210.

In some embodiments, the pedestal 210 is rotatable about a center axis 291 perpendicular to at least a portion of the upper surface 214 of the pedestal 210. In some embodiments, the pedestal 210 is rotatable about a vertical axis, which corresponds to the z-axis. In some embodiments, rotation of the pedestal 210 is continuous without indexing. In other words, a motor 231 driving rotation of the pedestal 210 does not have programmed stops for rotating the pedestal 210 to certain fixed rotational positions. Instead, the pedestal 210 is rotated continuously in relation to the target 212 to improve film uniformity. In some embodiments, the motor 231 is an electric servo motor. The motor 231 may be raised and lowered by a separate motor 215. The motor 215 may be an electrically powered linear actuator. A bellows 217 surrounds the pedestal shaft and forms a seal between the chamber body 202 and the motor 231 during raising and lowering of the pedestal 210.

An underside surface of the target 212, which is defined by a surface of a target material 212M, faces towards the upper surface 214 of the pedestal 210 and towards a front side of the substrate 216. The underside surface of the target 212 faces away from the backing plate 218, which faces towards the atmospheric region or external region of the PVD chamber 200. In some embodiments, the target materials 212M of the target 212 is formed from a metal for sputtering a corresponding film composition on the substrate 216. The target materials 212M includes one or more thermal interface materials, such as any of the thermal interface materials described herein.

In the illustrated embodiments, a plane that is parallel to the underside of the target 212 is tilted in relation to an upper surface of the support plate 213 by an angle 282 as shown in FIG. 2B. In other words, the plane of the target 212 is tilted in relation to a plane of the upper surface 214 of the pedestal 210 and, thus, in relation to the front side of the substrate 216. Because respective bodies of each of the pedestal 210 and the target 212 are generally planar, the target 212 may also be referred to as being tilted relative to the pedestal 210, and vice versa. In some embodiments, the angle 282 is about 10° to about 30° which results in a formation of a seed layer of thermal interface material with a tilted crystallographic orientation with respect to the substrate. When the substrate is a <100> crystallographic substrate, the tilted crystallographic orientation of the seed layer provides an angled nucleation layer onto which a further bulk layer of thermal interface material may be deposited, as discussed in greater detail below.

As shown in FIG. 2A, the target 212 is tilted downward in a direction from an inner radial edge 212C of the target 212 to an outer radial edge 212A of the target 212. In some situations, tilt angles above the range provided herein may have target-to-substrate spacing that varies too much from the inner radial edge 212C to the outer radial edge 212A, which can result in undesirable variation in film quality. In one example, an undesirable variation in film quality will include an undesirable variation in film roughness or grain size, or texture, or crystallographic orientation, or substrate center-to-edge uniformity. In another example, the undesirable variation in film quality can include an undesirable ratio of the amount of sputtered material provided to the surface of the substrate versus the amount of sputtered material provided to the shields that surround the substrate during a PVD process. Tilt angles below the range provided herein cause undesirable non-uniformity of the film.

In FIGS. 2A-2B, the pedestal 210 is substantially horizontal, or parallel to the x-y plane, whereas the target 212 is non-horizontal, or tilted in relation to the x-y plane. However, other non-horizontal orientations of the pedestal 210 are also contemplated. In some embodiments, the pedestal 210 may be tilted +/−15 degrees with respect to the horizontal direction.

A first actuator 220 may be coupled to the lid assembly 204 and to the magnetron 208 for oscillating the magnetron 208 in a circumferential direction centered about the rotational axis 293 of the first actuator 220 that is positioned near and at an angle 283 to the center axis 291. In some embodiments, the rotational axis 293 is perpendicular to the surface of the target 212. In some embodiments, as illustrated in FIG. 2B, the rotational axis 293 is disposed a distance from the magnetron 208 (e.g., nearest edge 208C of the magnetron 208) when measured relative to a plane that is perpendicular to the rotational axis 293. The first actuator 220 has a rotor 225 and a stator 227. The stator 227 is coupled to a support post 290 that is coupled to the support plate 213 of the lid assembly 204. The rotor 225 is coupled to a mounting plate 229 that is coupled to the magnetron 208 through a hinge 228 (described in detail below). In some configurations, the center axis 291 of the support post 290 is centered in relation to the chamber body 202 and the lid assembly 204. In some embodiments, the first actuator 220 is an electric motor. Alternatively, a pneumatic motor may be used. In some examples, the first actuator 220 may be a servo or stepper motor. In some examples, the first actuator 220 may be a direct drive motor, a belt drive motor, or a gear drive motor. In some embodiments, the first actuator 220 has program stops corresponding to the circumferential oscillation angle. In some embodiments, the first actuator 220 is an electric or pneumatic rotary actuator corresponding to the circumferential oscillation angle. However, other types of motors/actuators are also contemplated.

In the illustrated embodiments, a hinge 228 is used to couple a support body 230 of the magnetron 208 to the first actuator 220. The hinge 228 enables the magnetron 208 to be lifted and rotated out of the way of the backing plate 218, thereby facilitating access to the underside of the magnetron 208 and the topside of the backing plate 218 for performing maintenance, such as replacing the target 212.

As noted above, in some embodiments, the first actuator 220 is tilted in relation to the lid assembly 204. As shown in FIG. 2B, a rotational axis 293 of the first actuator 220 is tilted in relation to the center axis 291 of the support post 290 by an angle 283. The center axis 291 and rotational axis 293 intersect at a pivot point 295. In some embodiments, a rotational axis 293 of the first actuator 220 is perpendicular to the mounting plate 229, which is tilted in relation to the upper surface of the support plate 213 by an angle 281. The angles 281, 283 are equal, such that the distance between the lower surface of the magnetron 208 and the upper surface of the backing plate 218 remains constant as the magnetron 208 is translated over the surface of the backing plate 218 by use of the first actuator 220 and second actuator 222 during processing.

Referring back to FIGS. 2A-2B, a second actuator 222 is coupled between the magnetron 208 and the first actuator 220 to allow the magnetron 208 to be oscillated in a radial direction in relation to the target 212 and PVD chamber 200. The second actuator 222 is an electric linear actuator having a stroke distance corresponding to the desired radial oscillation distance. Alternatively, a pneumatic linear actuator may be used. In some embodiments, the second actuator 222 is an electric or pneumatic rotary motor with program stops corresponding to the radial oscillation distance. In some examples, the second actuator 222 may be a direct drive motor, a belt drive motor, or a gear drive motor that is coupled to lead-screw assembly, which can include a slide, that is used to guide the motion of the magnetron 208 in the desired radial direction. However, other types of motors/actuators are also contemplated.

The translation of the magnetron 208 over the surface of the backing plate 218 is used to achieve full-face erosion of the underside of the target 212, helps with defect management, and helps extend the life of the target 212 compared to a fixed magnet where only certain areas of the target 212 are eroded. In some embodiments, the first actuator 220 and second actuator 222 are synchronized to control the scanning path of the magnetron 208 in one or more directions across the backside of the backing plate 218.

In some embodiments, and as shown in FIG. 2A, a controller 250, such as a programmable computer, may be coupled to the PVD chamber 200 for controlling the PVD chamber 200 or components thereof. The controller 250 may represent the controller 130 of the system 100 in FIG. 1. For example, the controller 250 may control the operation of the PVD chamber 200 using direct control of the power source 206, the magnetron 208, the pedestal 210, cooling of the backing plate 218, the first actuator 220, the second actuator 222, the temperature control system 232, and/or the RF bias source 234, or using indirect control of other controllers associated therewith. In operation, the controller 250 enables data acquisition and feedback from the respective components to coordinate processing in the PVD chamber 200.

The controller 250 may include a programmable central processing unit (CPU) 252, which is operable with a memory 254 (e.g., non-volatile memory) and support circuits 256. The support circuits 256 (e.g., cache, clock circuits, input/output subsystems, power supplies, etc., and combinations thereof) are conventionally coupled to the CPU 252 and coupled to the various components of the PVD chamber 200.

In some embodiments, the CPU 252 is one of any form of general purpose computer processor used in an industrial setting, such as a programmable logic controller (PLC), for controlling various monitoring system components and sub-processors. The memory 254, coupled to the CPU 252, is non-transitory and is typically one or more of readily available memory such as random access memory (RAM), read only memory (ROM), floppy disk drive, hard disk, or any other form of digital storage, local or remote.

In some embodiments, the memory 254 may be in the form of a computer-readable storage media containing instructions (e.g., non-volatile memory), that when executed by the CPU 252, facilitates the operation of the PVD chamber 200. The instructions in the memory 254 are in the form of a program product such as a program that implements the methods of the present disclosure. The program code may conform to any one of a number of different programming languages. In one example, the disclosure may be implemented as a program product stored on computer-readable storage media for use with a computer system. The program(s) of the program product define functions of the embodiments (including the methods described herein).

Illustrative computer-readable storage media include, but are not limited to: (i) non-writable storage media (e.g., read-only memory devices within a computer such as CD-ROM disks readable by a CD-ROM drive, flash memory, ROM chips or any type of solid-state non-volatile semiconductor memory) on which information is permanently stored; and (ii) writable storage media (e.g., floppy disks within a diskette drive or hard-disk drive or any type of solid-state random-access semiconductor memory) on which alterable information is stored. Such computer-readable storage media, when carrying computer-readable instructions that direct the functions of the methods described herein, are embodiments of the present disclosure.

In operation, the PVD chamber 200 may be evacuated and back filled with argon gas. The power source 206 applies a negative bias voltage to the target 212 to generate an electric field inside the chamber body 202. The electric field acts to attract gas ions, which due to their collision with the exposed surface of the target 212, generates electrons that enable a high-density plasma to be generated and sustained near the underside of the target 212. The plasma is concentrated near the surface of target material 212M due to the magnetic field produced by the magnetron 208. The magnetic field forms a closed-loop annular path acting as an electron trap that reshapes the trajectories of the secondary electrons ejected from the target material 212M into a cycloidal path, greatly increasing the probability of ionization of the sputtering gas within the confinement zone. The plasma confined near the underside of the target 212 contains argon atoms, positively charged argon ions, free electrons, and neutral atoms (i.e., unionized atoms) sputtered from the target material 212M. The argon ions in the plasma strike the target surface and eject atoms of the target material, which are accelerated towards the substrate 216 to deposit a thin film on the substrate surface. Inert gases, such as argon, are usually employed as the sputtering gas because they tend not to react with the target material or combine with any process gases and because they produce higher sputtering and deposition rates due to their relatively high molecular weight.

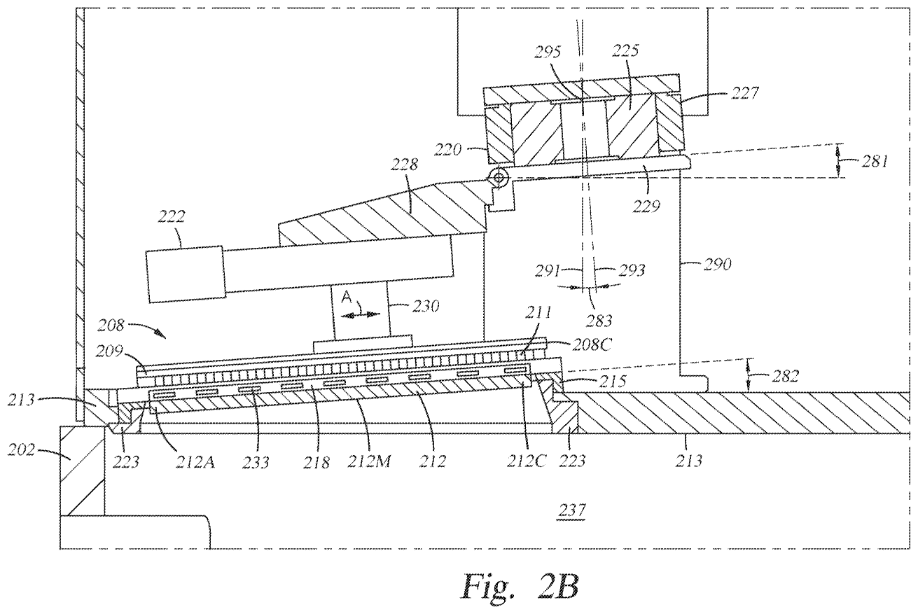

FIG. 3 is a schematic side cross-sectional view of a PVD chamber 300 that may be used in the system 100 of FIG. 1, according to some embodiments. For example, the PVD chamber 300 may represent at least one of the deposition chambers 116 shown in FIG. 1.

The PVD chamber 300 contains a substrate support pedestal 302 for receiving a substrate 304 thereon, and a sputtering source, such as a target 306. The target 306 may be formed of a thermal interface material, such as the thermal interface material described herein. The substrate support pedestal 302 may be located within a grounded chamber wall 308, which may be a chamber wall (as shown) or a grounded shield (a ground shield 340 is shown covering at least some portions of the PVD chamber 300 above the target 306. In some embodiments, the ground shield 340 could be extended below the target to enclose the pedestal 302 as well.).

In some embodiments, the process chamber includes a feed structure for coupling RF and DC energy to the target 306. The feed structure is an apparatus for coupling RF and DC energy to the target, or to an assembly containing the target, for example, as described herein. A first end of the feed structure can be coupled to an optional RF power source 318 and a DC power source 320, which can be respectively utilized to provide RF and DC energy to the target 306. For example, the DC power source 320 may be utilized to apply a negative voltage, or bias, to the target 306. In some embodiments, RF energy optionally supplied by the RF power source 318 may be suitable to provide frequency as described above, or range in frequency from about 2 MHz to about 60 MHz, or, for example, non-limiting frequencies such as 2 MHz, 13.56 MHz, 27.12 MHz, or 60 MHz can be used. In some embodiments, a plurality of RF power sources may optionally be provided (i.e., two or more) to provide RF energy in a plurality of the above frequencies. The feed structure may be fabricated from suitable conductive materials to conduct the RF and DC energy from the RF power source 318 and the DC power source 320. In embodiments, RF power source 318 is excluded, and DC power source 320 is configured to apply a negative voltage, or bias, to the target 306.

In some embodiments, the feed structure may have a suitable length that facilitates substantially uniform distribution of the respective RF and DC energy about the perimeter of the feed structure. For example, in some embodiments, the feed structure may have a length of between about 1 to about 12 inches, or about 4 inches. In some embodiments, the body may have a length to inner diameter ratio of at least about 1:1. Providing a ratio of at least 1:1 or longer provides for more uniform RF delivery from the feed structure (i.e., the RE energy is more uniformly distributed about the feed structure to approximate RF coupling to the true center point of the feed structure. The inner diameter of the feed structure may be as small as possible, for example, from about 1 inch to about 6 inches, or about 4 inches in diameter. Providing a smaller inner diameter facilitates improving the length to ID ratio without increasing the length of the feed structure.

The second end of the feed structure may be coupled to a source distribution plate 322. The source distribution plate includes a hole 324 disposed through the source distribution plate 322 and aligned with a central opening of the feed structure. The source distribution plate 322 may be fabricated from suitable conductive materials to conduct the RF and DC energy from the feed structure.

The source distribution plate 322 may be coupled to the target 306 via a conductive member 325. The conductive member 125 may be a tubular member having a first end 326 coupled to a target-facing surface 328 of the source distribution plate 322 proximate the peripheral edge of the source distribution plate 322. The conductive member 325 further includes a second end 330 coupled to a source distribution plate-facing surface 332 of the target 306 (or to the backing plate 346 of the target 306) proximate the peripheral edge of the target 306.

A cavity 334 may be defined by the inner-facing walls of the conductive member 325, the target-facing surface 328 of the source distribution plate 322 and the source distribution plate-facing surface 332 of the target 306. The cavity 334 is fluidly coupled to the central opening 315 of the body via the hole 324 of the source distribution plate 322. The cavity 334 and the central opening 315 of the body may be utilized to at least partially house one or more portions of a rotatable magnetron assembly 336 as illustrated in FIG. 3 and described further below. In some embodiments, the cavity may be at least partially filled with a cooling fluid, such as water (H₂O) or the like.

A ground shield 340 may be provided to cover the outside surfaces of the lid of the PVD chamber 300. The ground shield 340 may be coupled to ground, for example, via the ground connection of the chamber body. The ground shield 340 has a central opening to allow the feed structure to pass through the ground shield 340 to be coupled to the source distribution plate 322. The ground shield 340 may comprise any suitable conductive material, such as aluminum, copper, or the like. An insulative gap 339 is provided between the ground shield 340 and the outer surfaces of the source distribution plate 322, the conductive member 325, and the target 306 (and/or backing plate 346) to prevent the RF and DC energy from being routed directly to ground. The insulative gap may be filled with air or some other suitable dielectric material, such as a ceramic, a plastic, or the like.

In some embodiments, a ground collar may be disposed about the body and lower portion of the feed structure. The ground collar is coupled to the ground shield 340 and may be an integral part of the ground shield 340 or a separate part coupled to the ground shield to provide grounding of the feed structure. The ground collar may be made from a suitable conductive material, such as aluminum or copper. In some embodiments, a gap disposed between the inner diameter of the ground collar and the outer diameter of the body of the feed structure may be kept to a minimum and be just enough to provide electrical isolation. The gap can be filled with isolating material like plastic or ceramic or can be an air gap. The ground collar prevents cross-talk between the RF feed and the body, thus improving plasma, and processing, uniformity.

An isolator plate 338 may be disposed between the source distribution plate 322 and the ground shield 340 to prevent the RF and DC energy from being routed directly to ground. The isolator plate 338 has a central opening to allow the feed structure to pass through the isolator plate 338 and be coupled to the source distribution plate 322. The isolator plate 338 may comprise a suitable dielectric material, such as a ceramic, a plastic, or the like. Alternatively, an air gap may be provided in place of the isolator plate 338. In embodiments where an air gap is provided in place of the isolator plate, the ground shield 340 may be structurally sound enough to support any components resting upon the ground shield 340.

The target 306 may be supported, on a grounded conductive aluminum adapter such as 342 through a dielectric isolator 344. The target 306 comprises a material to be deposited on the substrate 304 during sputtering, such aluminum, or aluminum alloy. In some embodiments, the backing plate 346 may be coupled to the source distribution plate-facing surface 332 of the target 306. The backing plate 346 may comprise a conductive material, such as aluminum, or the same material as the target, such that RF and DC power can be coupled to the target 306 via the backing plate 346. Alternatively, the backing plate 346 may be non-conductive and may include conductive elements (not shown) such as electrical feedthroughs or the like for coupling the source distribution plate-facing surface 332 of the target 306 to the second end 330 of the conductive member 325. The backing plate 346 may be included for example, to improve structural stability of the target 306.

The substrate support pedestal 302 has a material-receiving surface facing the principal surface of the target 306 and supports the substrate 304 to be sputter coated in planar position opposite to the principal surface of the target 306. The substrate support pedestal 302 may support the substrate 304 in a central region 348 of the PVD chamber 300. The central region 348 is defined as the region above the substrate support pedestal 302 during processing (for example, between the target 306 and the substrate support pedestal 302 when in a processing position).

In some embodiments, the substrate support pedestal 302 may be vertically movable through a bellows 350 connected to a bottom chamber wall 352 to allow the substrate 304 to be transferred onto the substrate support pedestal 302 through a load lock valve (not shown) in the lower portion of processing the PVD chamber 300 and thereafter raised to a deposition, or processing position. One or more processing gases may be supplied from a gas source 354 through a mass flow controller 356 into the lower part of the PVD chamber 300. An exhaust port 358 may be provided and coupled to a pump (not shown) via a valve 360 for exhausting the interior of the PVD chamber 300 and facilitating maintaining a desired pressure of 2-10 mTorr inside the PVD chamber 300.

In some embodiments, substrate support pedestal 302 may be temperature controlled to maintain the temperature of the substrate between 200-500° C. during substrate processing. The substrate support pedestal 302 may include an air passage 371 for providing a back-side gas to substrate 304. In embodiments, closing air passage 371 and restricting the flow of back-side gas applied to a substrate 304 will increase the temperature of the substrate 304.

In some embodiments, an RF bias power source 362 may optionally be coupled to the substrate support pedestal 302 in order to induce a negative DC bias on the substrate 304. In addition, in some embodiments, a negative DC self-bias may form on the substrate 304 during processing. For example, RF power supplied by the RF bias power source 362 may range in frequency from about 2 MHz to about 60 MHz, for example, non-limiting frequencies such as 2 MHz, 13.56 MHz, or 60 MHz can be used. Further, a second RF bias power source 363 may be coupled to the substrate support pedestal 302 and provide any of the frequencies discussed above for use alone or optionally with the RF bias power source 362. In embodiments, a tuning network 398 may be positioned between RF bias power source 362 and the substrate support pedestal. In some embodiments, a second tuning network 399 may be positioned between the second RF bias power source 363 and the substrate support pedestal. In embodiments, second RF bias power source 363 is configured to provide the AC bias power to lower ion energy resulting in aluminum coalescing with the second layer of aluminum having a second grain size to increase the second grain size. In other applications, the substrate support pedestal 302 may be grounded or left electrically floating. For example, a capacitance tuner 364 may be coupled to the substrate support pedestal for adjusting voltage on the substrate 304 for applications where RF bias power may not be desired.

A rotatable magnetron assembly 336 may be positioned proximate a back surface (e.g., source distribution plate-facing surface 332) of the target 306. The rotatable magnetron assembly 336 includes a plurality of magnets 366 supported by a base plate 368. The base plate 368 connects to a rotation shaft 370 coincident with the central axis of the PVD chamber 300 and the substrate 304. A motor 372 can be coupled to the upper end of the rotation shaft 370 to drive rotation of the magnetron assembly 336. The magnets 366 produce a magnetic field within the PVD chamber 300, generally parallel and close to the surface of the target 306 to trap electrons and increase the local plasma density, which in turn increases the sputtering rate. The magnets 366 produce an electromagnetic field around the top of the PVD chamber 300, and magnets 366 are rotated to rotate the electromagnetic field which influences the plasma density of the process to more uniformly sputter the target 306. For example, the rotation shaft 370 may make about 0 to about 150 rotations per minute.

In some embodiments, the PVD chamber 300 may further include a process kit shield 374 connected to a ledge 376 of the adapter 342. The adapter 342 in turn is sealed and grounded to the aluminum chamber sidewall such as chamber wall 308. Generally, the process kit shield 374 extends downwardly along the walls of the adapter 342 and the chamber wall 308 downwardly to below an upper surface of the substrate support pedestal 302 and returns upwardly until reaching an upper surface of the substrate support pedestal 302 (e.g., forming a u-shaped portion 384 at the bottom). Alternatively, the bottommost portion of the process kit shield need not be a u-shaped portion 384 and may have any suitable shape. A cover ring 386 rests on the top of an upwardly extending lip 388 of the process kit shield 374 when the substrate support pedestal 302 is in a lower, loading position but rests on the outer periphery of the substrate support pedestal 302 when the substrate support pedestal 302 is in an upper, deposition position to protect the substrate support pedestal 302 from sputter deposition. An additional deposition ring (not shown) may be used to shield the periphery of the substrate 304 from deposition. Embodiments of a process kit shield are discussed below in accordance with the present disclosure.

In some embodiments, a magnet 390 may be disposed about the PVD chamber 300 for selectively providing a magnetic field between the substrate support pedestal 302 and the target 306. For example, as shown in FIG. 3, the magnet 390 may be disposed about the outside of the chamber wall 308 in a region just above the substrate support pedestal 302 when in processing position. In some embodiments, the magnet 390 may be disposed additionally or alternatively in other locations, such as adjacent the adapter 342. The magnet 390 may be an electromagnet and may be coupled to a power source (not shown) for controlling the magnitude of the magnetic field generated by the electromagnet.

A controller 310 may be provided and coupled to various components of the PVD chamber 300 to control the operation thereof. The controller 310 may be the controller 130 of the system 100. The controller 310 includes a central processing unit (CPU) 312, a memory 314, and support circuits 316. The controller 310 may control the PVD chamber 300 directly, or via computers (or controllers) associated with particular process chamber and/or support, system components. The controller 310 may be one of any form of general-purpose computer processor that can be used in an industrial setting for controlling various chambers and sub-processors. The memory, or computer readable medium, 434 of the controller 310 may be one or more of readily available memory such as random access memory (RAM), read only memory (ROM), floppy disk, hard disk, optical storage media (e.g., compact disc or digital video disc), flash drive, or any other form of digital storage, local or remote. The support circuits 316 are coupled to the CPU 312 for supporting the processor in a conventional manner. These circuits include cache, power supplies, clock circuits, input/output circuitry and subsystems, and the like. The methods as described herein may be stored in the memory 314 as software routine that may be executed or invoked to control the operation of the PVD chamber 300 in the manner described herein. The software routine may also be stored and/or executed by a second CPU (not shown) that is remotely located from the hardware being controlled by the CPU 312.

In some embodiments, the PVD chamber 300 may be used to deposit a thermal interface material directly onto a substrate or onto a seed layer of thermal interface material that has been previously deposited onto the substrate. As described in greater detail below, the PVD chamber 300 may be used to deposit a bulk layer of thermal interface material directly onto a <111> crystallographic substrate or a bulk layer of thermal interface material onto a seed layer of thermal interface material deposited onto a <100> crystallographic substrate.

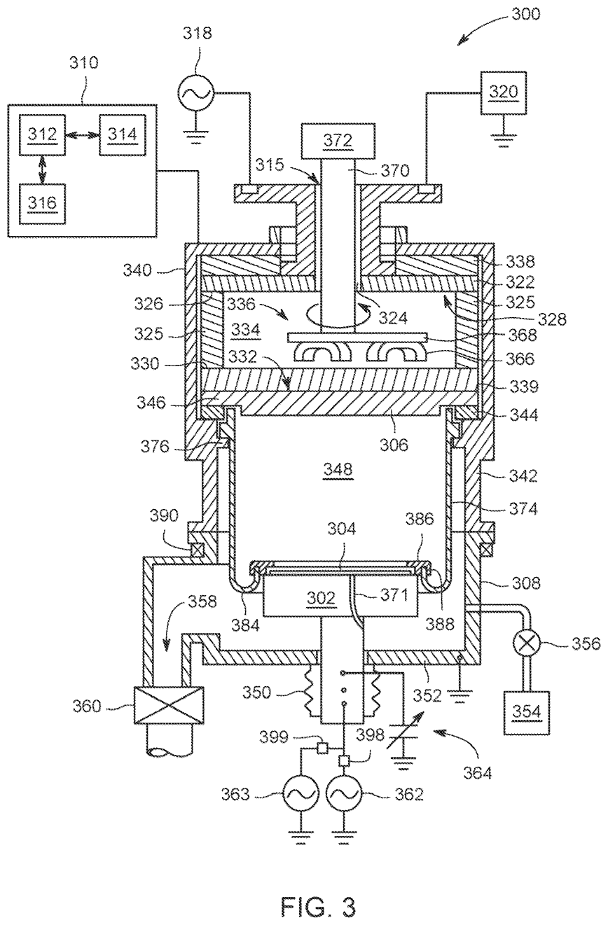

FIG. 4 depicts a method 400 for substrate processing in accordance with some embodiments of the present disclosure. At block 402, the method 400 may include sputtering a first seed layer having a first thickness on the substrate. In some embodiments, the first thickness is 5 nm-50 nm. The first seed layer may comprise predominantly a thermal interface material having a tilted crystallographic orientation with respect to the substrate. In some embodiments, the substrate is a <100> crystallographic substrate made of silicon. In some embodiments, the substrate may have other crystallographic orientations, including <110>. In some embodiments, depositing the first seed layer is performed in a PVD chamber orienting a sputter target at an angle of 10-30 degrees with respect to the substrate. In some embodiments, the method 400 includes rotating the substrate at 10-100 rpm during deposition of the first seed layer. The PVD chamber 200, or other suitable PVD chamber having a tilted target, may be used to perform the deposition at block 402.

At block 404, the method 400 includes sputtering a second layer having a second thickness on the first seed layer. In some embodiments, the second layer includes predominantly the thermal interface material and the second thickness is greater than the first thickness. In some embodiments, the second thickness is 50 nm-2000 nm. The bulk layer may be deposited with the substrate and the target relatively parallel to one another. The PVD chamber 300, or other PVD chamber having a target relatively parallel to the substrate, may be used to perform the deposition at block 404.

In some embodiments, the thermal interface material is aluminum nitride. In some embodiments, the first seed layer and the second layer have the same composition, e.g., aluminum nitride. In some embodiments, depositing the first seed layer is performed by PVD sputtering at a first power density and depositing the second layer is performed by PVD sputtering at a second power density that is higher than the first power density. In some embodiments, the first power density is 1-3 W/cm² and the second power density is 5-35 W/cm². In some embodiments, depositing the first seed layer may be performed in a first PVD chamber, such as the PVD chamber 200, and depositing the second layer may be performed in a second PVD chamber, such as the PVD chamber 300. The first seed layer and the second layer may be deposited with or without a vacuum break in-between.

At block 406, the method 400 may include polishing the second layer (e.g., in the polishing chamber 108 or other suitable polishing chamber) until a surface roughness of the second layer is suitable for at least one of fusion bonding, thermal compression bonding, or hybrid bonding. In some embodiments, polishing is performed until a surface roughness Ra of the second layer is 0.2 to 2 nm. Polishing may include chemical mechanical polishing (CMP). The polishing may be performed in one or more stages to achieve a desired surface roughness Ra.

At block 408, the method 400 may include bonding the substrate to another substrate, as discussed in greater detail below. For example, the polished substrate may be transferred to a bonding chamber (e.g., of the system 100) where the polished substrate may be bonded to another substrate using any wafer-to-wafer bonding techniques, such as hybrid bonding, fusion bonding, and thermal compression bonding.

In the case of thermal interface material made from AlN, without depositing the first seed layer on a <100> crystallographic substrate, a bulk layer of thermal interface material deposited directly on the substrate can be difficult to polish by chemical mechanical polishing without experiencing a highly non-uniform material removal rate across the substrate. The embodiments described herein include depositing the first seed layer (with a tilted crystallographic orientation with respect to the substrate) onto the substrate before depositing the second layer. Following the deposition, the second layer may be polished with highly uniform material removal rates across the substrate. The first seed layer provides an angled nucleation layer that prevents the non-uniform material removal rate across the substrate.

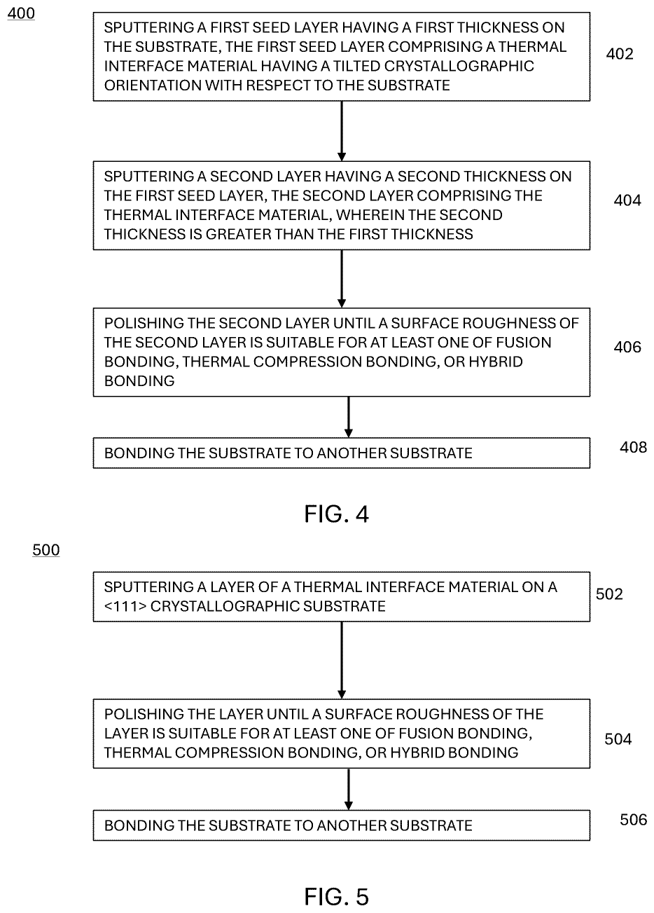

FIG. 5 depicts a method 500 for substrate processing in accordance with some embodiments of the present disclosure. At block 502, the method 500 may include sputtering a layer of a thermal interface material on a <111> crystallographic substrate (e.g., without prior deposition of a seed layer). In some embodiments, the thermal interface material is aluminum nitride. In some embodiments, the layer has a thickness of 50 nm-2000 nm. The PVD chamber 300, or other PVD chamber having a target relatively parallel to the substrate, may be used to perform the deposition at block 502. In some embodiments, the layer is sputtered by PVD sputtering at a power density of 5-35 W/cm².

At block 504, the method 500 may include polishing the layer (e.g., in the polishing chamber 108 or other suitable polishing chamber) until a surface roughness Ra of the layer is suitable for at least one of fusion bonding, thermal compression bonding, or hybrid bonding. In some embodiments, polishing is performed until the surface roughness Ra of the layer is 0.2 to 2 nm. In some embodiments, polishing includes chemical mechanical polishing (CMP). The polishing may be performed in one or more stages to achieve a desired surface roughness Ra.

At block 506, the method 500 may include bonding the substrate to another substrate, as discussed in greater detail below. For example, the polished substrate may be transferred to a bonding chamber (e.g., of the system 100) where the polished substrate may be bonded to another substrate using any wafer-to-wafer bonding techniques, such as hybrid bonding, fusion bonding, and thermal compression bonding.

In comparison to the method 400, the method 500 allows deposition of a bulk layer of thermal interface materials directly onto <111> crystallographic substrates, and without the use of an intermediate seed layer of thermal interface material. As a result, the method 500 may provide a higher throughput than the method 400.

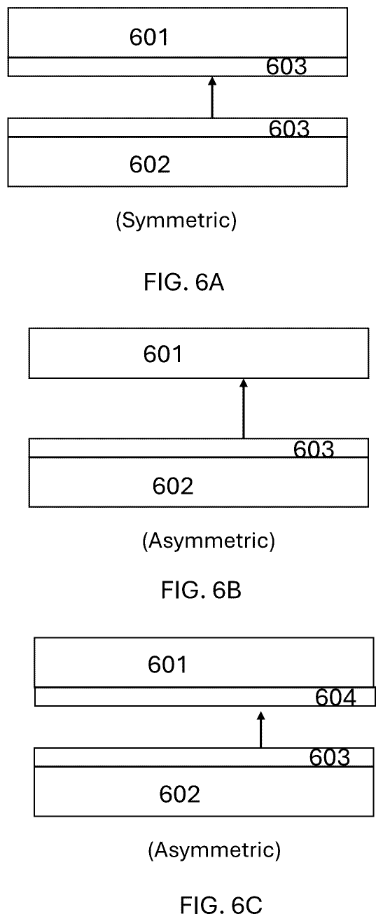

FIGS. 6A-6C depict examples of bonding a substrate 602 having a thermal interface material 603 that may be deposited in accordance with methods of the present disclosure, such as methods 400 and 500. The bonding procedure may be carried out using any known wafer-to-wafer bonding techniques (e.g. hybrid bonding, fusion bonding, thermal compression bonding), except for the deposition of the thermal interface layer in accordance with the teachings provided herein. FIG. 6A depicts an example of symmetric bonding of two substrates 602 at opposing surface of the thermal interface material. FIG. 6B depicts an example of asymmetric bonding of two substrates 601 and 602. Substrate 601 does not have any layer of thermal interface material deposited thereon. Substrate 602 has thermal interface material 603 that may be deposited in accordance with methods of the present disclosure, such as methods 400 and 500. The substrate 601 is bonded to substrate 602 along the interface material 603. FIG. 6C depicts an example of asymmetric bonding of a substrate 601 having a non-thermal interface material 604 (e.g., SiO₂, SiN, high K dielectric, or electrically non-conducting metal oxide) deposited thereon and a substrate 602 having a thermal interface material 603 that may be deposited in accordance with methods of the present disclosure, such as methods 400 and 500. The non-thermal interface material has a thermal conductivity that is less than a thermal interface material.

Systems and methods are provided for depositing and polishing thermal interface material on substrates that are suitable for at least one of fusion bonding, thermal compression bonding, or hybrid bonding. In comparison to other methods of deposition, the systems and methods provided for herein utilize PVD deposition, which provides cost and throughput advantages.

While the foregoing is directed to embodiments of the present disclosure, other and further embodiments of the disclosure may be devised without departing from the basic scope thereof.

1. A method of processing a substrate, the method comprising:
sputtering a first seed layer having a first thickness on the substrate, the first seed layer comprising a thermal interface material having a tilted crystallographic orientation with respect to the substrate;
sputtering a second layer having a second thickness on the first seed layer, the second layer comprising the thermal interface material; and
polishing the second layer until a surface roughness of the second layer is suitable for at least one of fusion bonding, thermal compression bonding, or hybrid bonding.

2. The method of claim 1, wherein the substrate is a <100> crystallographic substrate.

3. The method of claim 1, wherein the second thickness is greater than the first thickness.

4. The method of claim 1, wherein the first thickness is 5 nm-50 nm and the second thickness is 50 nm-2000 nm.

5. The method of claim 1, wherein the thermal interface material is aluminum nitride.

6. The method of claim 1, wherein the first seed layer and the second layer have the same composition.

7. The method of claim 1, further comprising hybrid bonding the substrate along the second layer to another substrate.

8. The method of claim 1, wherein depositing the first seed layer is performed by PVD sputtering at a first power density and depositing the second layer is performed by PVD sputtering at a second power density that is higher than the first power density.

9. The method of claim 8, wherein the first power density is 1-3 W/cm² and the second power density is 5-35 W/cm².

10. The method of claim 1, wherein the first seed layer is performed in a PVD chamber orienting a sputter target at an angle of 10-30 degrees with respect to the substrate.

11. The method of claim 1, wherein polishing includes chemical mechanical polishing.

12. The method of claim 1, wherein polishing is performed until a surface roughness Ra of the second layer is 0.2 to 2 nm.

13. A method of processing a substrate, the method comprising:
sputtering a layer of a thermal interface material on a <111> crystallographic substrate; and
polishing the layer until a surface roughness of the layer is suitable for at least one of fusion bonding, thermal compression bonding, or hybrid bonding.

14. The method of claim 13, wherein the thermal interface material is aluminum nitride.

15. The method of claim 13, wherein the layer has a thickness of 50 nm-2000 nm.

16. The method of claim 13, further comprising hybrid bonding the substrate along the layer to another substrate.

17. The method of claim 13, wherein polishing is performed until a surface roughness Ra of the layer is 0.2 to 2 nm.

18. A system for processing a substrate, the system comprising:
at least one PVD chamber;
a polishing chamber; and
a controller configured to control the at least one PVD chamber and the polishing chamber to:
sputter a layer of aluminum nitride on the substrate; and
polish the layer until a surface roughness Ra of the layer is 0.2 to 2 nm.

19. The system of claim 18, wherein the controller is further configured to control the at least one PVD chamber to sputter a seed layer of aluminum nitride onto the substrate before sputtering the layer, the seed layer having a thickness that is less than a thickness of the layer.

20. The system of claim 19, wherein the controller is configured to control the at least one PVD chamber to sputter the seed layer at a first power density and sputter the layer at a second power density that is higher than the first power density.
